(19) United States
(12) Patent Application Publication
(10) Pub. No.: US 2021/0257596 A1
(43) Pub. Date: Aug. 19, 2021

(54) Display Module and Electronic Device

(71) Applicant: WUHAN CHINA STAR OPTOELECTRONICS TECHNOLOGY CO., LTD., Wuhan (CN)

(72) Inventor: Yuejun TANG, Wuhan (CN)

(21) Appl. No.: 16/099,702

(22) PCT Filed: Sep. 13, 2018
(86) PCT No.: PCT/CN2018/105441

§ 371 Date: Nov. 8, 2018

(30) Foreign Application Priority Data
Aug. 31, 2018 (CN) 201811015670.5

(51) Int. Cl. H01L 51/52; H01L 27/32

(52) U.S. Cl. CPC H01L 51/5293; H01L 51/5246; H01L 27/3232

(57) ABSTRACT

The present application provides a display module and an electronic device. The display module comprises a display panel and polarizer layers located on the display panel The polarizer layers comprises a first phase layer, a linear polarizing layer on the first phase layer, and a second phase layer on the linear polarizing layer. The first phase layer and the second phase layer are λ/4 wave plates. A compensation value of the λ/4 wave plates is 1/4 of a corresponding wavelength.

### BACKGROUND

### 1. Field of the Disclosure

The present application relates to the field of display, more particularly, to a display module and an electronic device.

### 2. Description of the Related Art

In the flat panel display technology, the OLED (Organic Light-Emitting Diode) display has many advantages, such as light and thin, active illumination, fast response, large viewing angle, wide color gamut, high brightness and low power consumption, and gradually becomes the third generation display technology after liquid crystal displays.

The outermost layer of the polarizer layers of the now existing OLED display is a linear polarizer, and the sunglasses also have the function of a linear polarizer. Hence, when the absorption axis of the sunglasses is orthogonal to the absorption axis of the outermost polarizer of the OLED display, the invisible situation occurs. That is, the now existing OLED display does not take the effect of sunglasses into consideration.

Therefore, the related art cannot allow users to see the OLED display at any angle when wearing the sunglasses.

### SUMMARY

The present application provides a display module and an electronic device to resolve the technical problem that users can not see the OLED display at any angle when wearing the sunglasses.

The present application provides a display module. The display module comprises a display panel and polarizer layers located on the display panel. The polarizer layers comprises a first phase layer, a linear polarizing layer on the first phase layer, and a second phase layer on the linear polarizing layer. The first phage layer and the second phase layer are λ/4 wave plates. A compensation value of the λ/4 wave plates is ¼ of a corresponding wavelength.

Optionally, the display module further comprises a third phase layer, the third phase layer is located between the first phase layer and the linear polarizing layer.

Optionally, the third phase layer is a λ/2 wave plate, and a compensation value of the λ/2 wave plate is ½ of a corresponding wavelength.

Optionally, the display module further comprises at least one adhesive layer, the adhesive layer is disposed closely adjacent to the first phase layer or/and the second phase layer.

Optionally, the adhesive layer comprise a first adhesive layer, the first adhesive layer is located between the display module and the first phase layer.

Optionally, the adhesive layer limber comprises a second adhesive layer, the second adhesive layer is located between the first phase layer and the linear polarizing layer.

Optionally, the adhesive layer further comprises a third adhesive layer, the third adhesive layer is located between the second phase layer and the linear polarizing layer.

Optionally, the display module further comprises at least one support layer, the support layer is disposed closely adjacent to the linear polarizing layer.

Optionally, the support layer comprises a first support layer and a second support layer. The first support layer is located between the second adhesive layer and the linear polarizing layer, and the second support layer is located between the third adhesive layer and the linear polarizing layer.

The present application also provides an electronic device comprising a display module. The display module comprises a display panel and polarizer layers located on the display panel. The polarizer layers comprises a first phase layer, a linear polarizing layer on the first phase layer, a second phase layer on the linear polarizing layer, and a third phase layer located between the first phase layer and the linear polarizing layer. The first phase layer and the second phase layer are λ/4 wave plates. A compensation value of the λ/4 wave plates is ¼ of a corresponding wavelength.

Optionally, the third phase layer is a λ/2 wave plate, and a compensation value of the λ/2 wave plate is ½ of a corresponding wavelength.

Optionally, the display module further comprises at least one adhesive layer, the adhesive layer is disposed closely adjacent to the first phase layer or/and the second phase layer.

Optionally, the adhesive layer comprises a first adhesive layer. The first adhesive layer is located between the display module and the first phase layer.

Optionally, the adhesive layer further comprises a second adhesive layer, the second adhesive layer is located between the first phase layer and the linear polarizing layer.

Optionally, the adhesive layer further comprises a third adhesive layer, the third adhesive layer is located between the second phase layer and the linear polarizing layer.

Optionally, the display module further comprises at least one support layer, the support layer is disposed closely adjacent to the linear polarizing layer.

Optionally, the support layer comprises a first support layer and a second support layer. The first support layer is located between the second adhesive layer and the linear polarizing layer, and the second support layer is located between the third adhesive layer and the linear polarizing layer.

The present application further provides an electronic device comprising the above display module.

The advantageous effects are as follows: the present application disposes phase layers that are λ/4 wave plates on both sides of the linear polarizing layer to allow the light emitted by the display panel to become circularly polarized light after passing through the first phase layer, the linear polarizing layer and the second phase layer. As a result, users wearing sunglasses are able to see the OLED display at any angle.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a structural diagram of film layers of a display module according to a first embodiment of the present application.

FIG. 2 is a structural diagram of film layers of a display module according to a second embodiment of the present application.

FIG. 3 is a structural diagram of film layers of a display module according to a third embodiment of the present application.

FIG. 4 is a structural diagram of film layers of a display module according to a fourth embodiment of the present application.

FIG. 5 is a structural diagram of film layers of a display module according to a fifth embodiment of the present application.

### DESCRIPTION OF THE EMBODIMENTS

In the disclosure, it is should be understood that spatially relative terms, such as “center”, “longitudinal”, “lateral”, “length”, “width”, “above”, “below”, “front”, “back”, “left”, “right”, “horizontal”, “vertical”, “top”, “bottom”, “inner”, “outer”, “clockwise”, “counterclockwise”, “axial”, “radial”, “circumferential”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The spatially relative terms are not limited to specific orientations depicted in the figures.

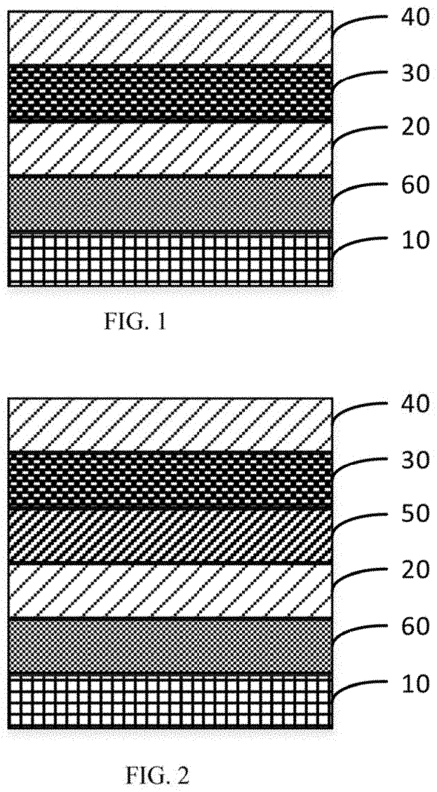

FIG. 1 is a structural diagram of film layers of a display module according to a first embodiment of the present application. The display module comprises a display panel 10 and polarizer layers located on the display panel 10. The polarizer layers comprise a first phase layer 20, a linear polarizing layer 30 on the first phase layer 20, and a second phase layer 40 on the linear polarizing layer 30.

In greater detail, the display panel may be, but not limited to, a liquid crystal display panel or an OLED display panel. The following embodiments will be described by taking an OLED display panel as an example.

The OLED display panel comprises an array substrate, a light-emitting device layer on the array substrate, and a thin film encapsulation layer on the light-emitting device layer. It can be understood that the array substrate may be, but not limited to, a flexible substrate. Preferably, a flexible material may be a polyimide film.

In the display module according to the present application, the first phase layer 20 and the second phase layer 40 are λ/4 wave plates for convening linearly polarized light into circularly polarized light, or converting circularly polarized light into linearly polarized light.

The linear polarizing layer 30 may also be referred to as a polyvinyl alcohol (PVA) layer. The linear polarizing layer 30 is a core portion of the polarizer layers, and is mainly used the absorbing light of one polarization state in natural light and transmitting the light of another polarization state to obtain the polarized light. Preferably, a thickness of the linear polarizing layer 30 is generally set at 20 micrometers (um).

The natural light directly enters into the display module through the second phase layer 40. Only when the linearly polarized light passes through the phase layer, will the phase change correspondingly, that is, become circularly polarized light.

In the present embodiment, the natural light does not have any change correspondingly when passing through the second phase layer 40, and then becomes first linearly polarized light after passing through the linear polarizing layer 30. The first linearly polarized light is convened into first circularly polarized light after passing through the first phase layer 20. Owing to the reflection effect of the surface metal layer (that is, the cathode layer) of the light-emitting device layer, the first circularly polarized light will re-enter the first phase layer 20, that is, the first circularly polarized light will be converted into second linearly polarized light.

The first phase layer 20 is a λ/4 wave plate, and therefore a phase difference between the first linearly polarized light and the second linearly polarized fight is λ/2 after passing through the first phase layer 20 twice. That is, polarization directions of the first linearly polarized light and the second linearly polarized light are perpendicular to each other. The second linearly polarized light is blocked since it can not pass through the linear polarizing layer 30. A compensation value of the λ/4 wave plates is ¼ of a corresponding wavelength.

Similarly, light emitted by the light-emitting device layer (which can also be understood as natural light) does not have any change correspondingly when passing through the first phase layer 20, and then becomes linearly polarized light after passing through the linear polarizing, layer 30. The linearly polarized light is converted into circularly polarized light after passing through the second phase layer 40 to allow users wearing sunglasses to see the OLEO display at any angle.

In addition, the polarizer layers according to the present embodiment further comprise a first adhesive layer 60 between the display panel 10 and the first phase layer 20.

In greater detail, the first phase layer 20 and the second phase layer 40 simultaneously function as phase layers and support/protective layers of the linear polarizing layer. In addition to that, the polarizer layers in the present embodiment have a smaller thickness when compared with the polarizer layers of the related art, thus reducing the film thickness of the display module.

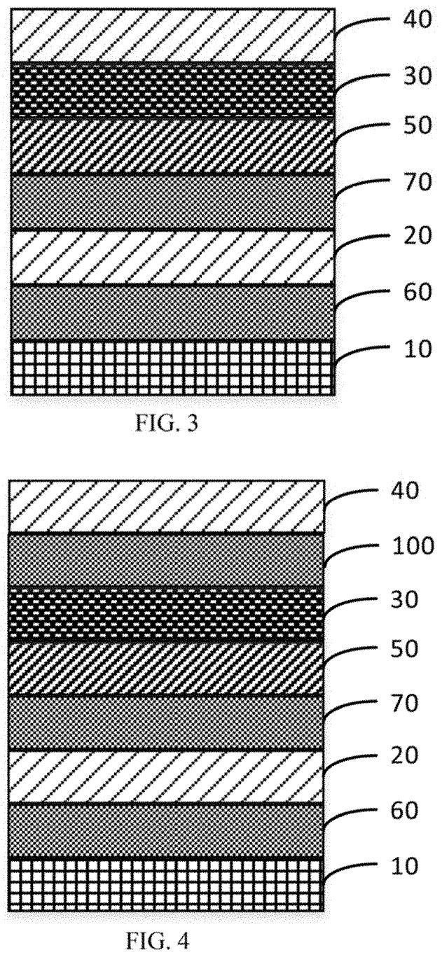

FIG. 2 is a structural diagram of film layers of a display module according to a second embodiment of the present application. As compared with the first embodiment, the display module according to the present application further comprises a third phase layer 50. The third phase layer 50 is located between the first phase layer 20 and the linear polarizing layer 30. The third phase layer 50 is a λ/2 wave plate for changing a polarization state of linearly polarized light to another predetermined direction, or changing a direction of the circularly polarized light to an opposite direction. A compensation value of the λ/2 wave plate is ½ of a corresponding wavelength.

When the natural light enters into the display module according to the present embodiment, first linearly polarized light is formed after passing through the linear polarizing layer 30, and then second linearly polarized light is formed after passing through the first phase layer 20 twice and the third phase layer 50 twice. When the first linearly polarized light is compared with the second linearly polarized light, a phase difference is 3λ/2. Polarization directions of the first linearly polarized light and the second linearly polarized light are perpendicular to each other. The second linearly polarized light is blocked since it can not pass through the linear polarizing layer 30.

Similarly, light emitted by the light-emitting device layer (which can also be understood as natural light) does not have any change correspondingly when passing through the first phase layer 20 and the third phase layer 50, and then becomes linearly polarized light after passing through the linear polarizing layer 30. The linearly polarized light is converted into circularly polarized light after passing through the first phase layer 20 to allow users wearing sunglasses to see the OLED display at any angle.

In addition, in the display module of the present application, the display module further comprises at least one adhesive layer. The adhesive layer is disposed closely adjacent to the first phase layer 20 or/and the second phase layer 40.

The adhesive layer may also be referred to as a pressure sensitive adhesive (PSA) layer, that is, a material that achieves surface bonding of the bonded object by pressure. The effect of the adhesive layer in the polarizer layers is to ensure that the polarizer can be reliably adhered to a surface of the encapsulation layer.

Preferably, a thickness of the adhesive layer is generally set at 20 um.

As shown in FIG. 3, on the basis of the first embodiment and the second embodiment, the adhesive layer in the third embodiment may further comprise a second adhesive layer 70. The second adhesive layer 70 is located between the first phase layer 20 and the third phase layer 50.

Since a working principle of the third embodiment is the same as that of the first embodiment and the second embodiment, a description in this regard is not provided.

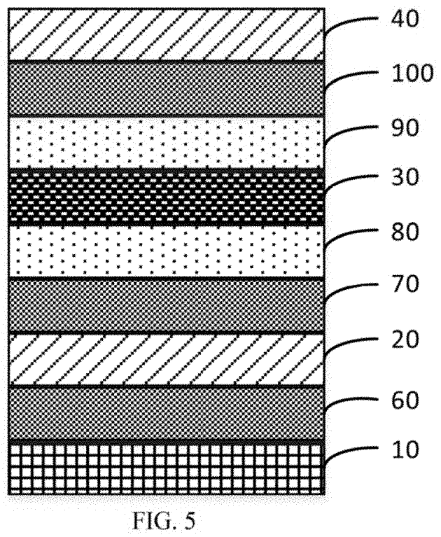

FIG. 4 is a structural diagram of film layers of a display module according to a fourth embodiment of the present application. The adhesive layer comprises the first adhesive layer 60, the second adhesive layer 70 and a third adhesive layer 100 on the basis of the third embodiment. The first adhesive layer 60 is located between the first phase layer 20 and the display panel 10. The second adhesive layer 70 is located between the first phase layer 20 and the third phase layer 50. The third adhesive layer 100 is located between the second phase layer 40 and the linear polarizing layer 30.

It can be understood that since a working principle of the fourth embodiment is the same as that of the first embodiment to the third embodiment, a description in this regard is not provided.

FIG. 5 is a structural diagram of film layers of a display module according to a fifth embodiment of the present application. FIG. 5 differs from the previous embodiments in that:

The display module according to the present embodiment further comprises at least one support layer. The support layer is disposed closely adjacent to the linear polarizing layer 30. The support layer may be referred to as a triacetate (TAC) layer, and the support layer mainly functions to support and protect the underlying PVA layer in the polarizer layers, that is, the support layers are generally disposed on both sides of linear polarizing layer 30.

Preferably, a thickness of the TAC layer is generally set at 40 um to 60 um.

In greater detail, as shown in FIG. 5, the support layer comprises a first support layer 80 and a second support layer 90. The first support layer 50 is located between the second adhesive layer 70 and the linear polarizing layer 30. The second support layer 90 is located between the third adhesive layer 100 and the linear polarizing layer 30.

In the first embodiment to the fifth embodiment of the present application, the first phase layer 20, the second phase layer 40, and the third phase layer 50 may be a birefringent film, an oriented film made of a liquid crystal polymer, or a film supported by an oriented film made of a liquid crystal polymer that is formed by stretching a film made of at least one polymer of polycarbonate, polyvinyl alcohol, polystyrene, poly(methyl methacrylate), polypropylene, polyolefin, polyarylate, and polyamide.

Additionally, a surface of the second phase layer 40 may be hardened or anti-glare treated.

The present application further provides an electronic device comprising the above display panel. The electronic device comprises, but not limited to, a mobile phone, a tablet computer, a computer display, a game machine, a television, a display screen, a wearable device, or some other daily electrical device or household appliance having a display function.

The present application provides a display module and an electronic device. The display module comprises a display panel and polarizer layers located on the display panel. The polarizer layers comprises a first phase layer, a linear polarizing layer on the first phase layer, and a second phase layer on the linear polarizing layer. The first phase layer and the second phase layer are λ/4 wave plates. A compensation value of the λ/4 wave plates is ¼ of a corresponding wavelength. The present application disposes phase layers that are λ/4 wave plates on both sides of the linear polarizing layer to allow the light emitted by the display panel to become circularly polarized light after passing through the first phase layer, the linear polarizing layer and the second phase layer. As a result, users wearing, sunglasses are able to see the OLED display at any angle.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

What is claimed is:

1. A display module comprising a display panel and polarizer layers located on the display panel, the polarizer layers comprising:
a first phase layer;
a linear polarizing layer on the first phase layer; and
a second phase layer on the linear polarizing layer;
wherein the first phase layer and the second phase layer are λ/4 wave plates, and a compensation value of the λ/4 wave plates is ¼ of a corresponding wavelength.

2. The display module as claimed in claim 1, wherein the display module further comprises a third phase layer, the third phase layer is located between the first phase layer and the linear polarizing layer.

3. The display module as claimed in claim 2, wherein the third phase layer is a λ/2 wave plate, and a compensation value of the λ/2 wave plate is ½ of a corresponding wavelength.

4. The display module as claimed in claim 1, wherein the display module further comprises at least one adhesive layer, the adhesive layer is disposed closely adjacent to the first phase layer or/and the second phase layer.

5. The display module as claimed in claim 4, wherein the adhesive layer comprise a first adhesive layer, the first adhesive layer is located between the display module and the first phase layer.

6. The display module as claimed in claim 5, wherein the adhesive layer further comprises a second adhesive layer, the second adhesive layer is located between the first phase layer and the linear polarizing layer.

7. The display module as claimed in claim 6, wherein the adhesive layer further comprises a third adhesive layer, the third adhesive layer is located between the second phase layer and the linear polarizing layer.

8. The display module as claimed in claim 7, wherein the display module further comprises at least one support layer, the support layer is disposed closely adjacent to the linear polarizing layer.

9. The display module as claimed in claim 8, wherein the support layer comprises a first support layer and a second support layer;
the first support layer being located between the second adhesive layer and the linear polarizing layer, the second support layer being located between the third adhesive layer and the linear polarizing layer.

10. An electronic device comprising a display module that comprises a display panel and polarizer layers located on the display panel, the polarizer layers comprising:
a first phase layer;
a linear polarizing layer on the first phase layer; and
a second phase layer on the linear polarizing layer;
a third phase layer located between the first phase layer and the linear polarizing layer,
wherein the first phase layer and the second phase layer are λ/4 wave plates.

11. The electronic device as claimed in claim 10, wherein the third phase layer is a λ/2 wave plate, and a compensation value of the λ/2 wave plate is ½ of a corresponding wavelength.

12. The electronic device as claimed in claim 10, wherein the display module further comprises at least one adhesive layer, the adhesive layer is disposed closely adjacent to the first phase layer or/and the second phase layer.

13. The electronic device as claimed in claim 12, wherein the adhesive layer comprise a first adhesive layer, the first adhesive, layer is located between the display module and the first phase layer.

14. The electronic device as claimed in claim 13, wherein the adhesive layer further comprises a second adhesive layer, the second adhesive layer is located between the first phase layer and the linear polarizing layer.

15. The electronic device as claimed in claim 14, wherein the adhesive layer further comprises a third adhesive layer, the third adhesive layer is located between the second phase layer and the linear polarizing layer.

16. The electronic device as claimed in claim 15, wherein the display module further comprises at least one support layer, the support layer is disposed closely adjacent to the linear polarizing layer.

17. The electronic device as claimed in claim 16, wherein the support layer comprises a first support layer and a second support layer;
the first support layer being located between the second adhesive layer and the linear polarizing layer, the second support layer being located between the third adhesive layer and the linear polarizing layer.
